(19) United States
(12) Patent Application Publication
(10) Pub. No.: US 2025/0192046 A1
(43) Pub. Date: Jun. 12, 2025

(54) ASYMMETRIC VIA BAR UNDER POWER RAIL

(71) Applicant: International Business Machines Corporation, Armonk, NY (US)

(72) Inventors: Ruilong Xie, Niskayuna, NY (US); Nicholas Anthony Lanzillo, Wynantskill, NY (US); Albert M. Chu, Nashua, NH (US); Brent A. Anderson, Jericho, VT (US); Lawrence A. Clevenger, Saratoga Springs, NY (US); Reinaldo Vega, Mahopac, NY (US)

(21) Appl. No.: 18/532,603

(22) Filed: Dec. 7, 2023

(51) Int. Cl. H01L 23/528; H01L 21/8234; H01L 23/522; H01L 23/535; H01L 27/088; H01L 29/06; H01L 29/08; H01L 29/423; H01L 29/66; H01L 29/775; H01L 29/786

(52) U.S. Cl. CPC H01L 23/5286; H01L 23/5226; H01L 23/5283; H01L 23/535; H10D 30/014; H10D 30/43; H10D 30/6735; H10D 30/6757; H10D 62/115; H10D 62/121; H10D 62/151; H10D 64/017; H10D 84/0135; H10D 84/0149; H10D 84/038; H10D 84/83

(57) ABSTRACT

A semiconductor device includes a gate cut disposed through a space between source/drain regions and corresponding source/drain contacts. The gate cut has a top surface above a top surface of the source/drain contacts. An asymmetric via is disposed on and wraps around a side of a top portion of the gate cut to connect one of the source/drain contacts to a power rail.

### BACKGROUND

The present invention generally relates to semiconductor devices and processing methods, and more particularly to a via or via bar connection to a power rail that is offset and asymmetric to connect to middle of the line contacts and corresponding structures.

Power rails are provided to supply power and ground to transistor devices on a chip. A power rail, e.g., on a first metal layer after middle end of line (MOL) contacts are formed, can be connected to MOL contacts by a via or via bar. The via or via bar is formed symmetrically with the metal line of the first metal layer to conserve space and to provide adequate contact area between the structures. However, with ever-decreasing node sizes, the space available for such a via has shrunk to the point where a neighboring source/drain contact is too close to the via. This results in the need to push the neighboring source/drain contact away from a transistor cell boundary to which the neighboring via or via bar connects. This leads to inadequate contact area between the source/drain contact and the source/drain epi. If the source/drain contact position is kept in place, to maintain spacings, the neighboring via or via bar is no longer well-positioned and its effectiveness is reduced due to its placement and/or due to a reduction in its size.

The problem is amplified when an N2N space, i.e., a spacing between adjacent n-type field effect transistors (NFETs), or a P2P space, i.e., a spacing between adjacent p-type field effect transistors (PFETs), decreases. These decreases in device size limit options for the placement of adequately sized contacts in N2N and P2P spacings making connections of the via or via bar to a power rail (PR) which is located above a cell boundary (e.g., over the N2N or P2P space) very difficult.

Therefore, a need exists for alternate connection methods and wiring that preserve the electrical integrity of conductive components but provide efficient wire routing within the constraints of ever decreasing node sizes.

### SUMMARY

In accordance with an embodiment of the present invention, a semiconductor device includes a gate cut disposed through a space between source/drain regions and corresponding source/drain contacts. The gate cut has a top surface above a top surface of the source/drain contacts. An asymmetric via is disposed on and wraps around a side of a top portion of the gate cut to connect one of the source/drain contacts to a power rail.

In some embodiments, the gate cut can be disposed within a shallow trench isolation. A via can be connected to the other source/drain contact at a position on the contact or a side opposite the gate cut to provide space between the via and the asymmetric via. The asymmetric via can include a via bar with an asymmetric cross-section. The asymmetric via is preferably offset from a centerline of the power rail. Dielectric portions can be disposed within trimmed portions of the asymmetric via to ensure isolation between the asymmetric via and a neighboring metal line. This is especially useful when a lower dimension of a cross-section of the neighboring metal line exceeds a top dimension of the cross-section of the neighboring metal line. This condition exists when subtractive etching is employed to fabricate the metal layer (e.g., M1). The gate cut can be tapered to be wider than the space at the top portion.

In accordance with another embodiment of the present invention, a semiconductor device includes a first source/drain region and a second source/drain region adjacent to the first source/drain region. The first source/drain region and second source/drain region have a space therebetween. A first contact is connected to the first source/drain region, and a second contact is connected to the second source/drain region. A gate cut is disposed through the space and extends between and above the first contact and the second contact. An asymmetric via is disposed on and wraps around a side of a top portion of the gate cut to connect the first contact to a power rail.

In some embodiments, the gate cut can be disposed within a shallow trench isolation. A via can be connected to the second contact at a position opposite the gate cut. The asymmetric via can include a via bar with an asymmetric cross-section. The asymmetric via can be offset from a centerline of the power rail. Dielectric portions can be disposed within trimmed portions of the asymmetric via to ensure isolation between the asymmetric via and a neighboring metal line, when a lower dimension of a cross-section of the neighboring metal line exceeds a top dimension of the cross-section of the neighboring metal line. The gate cut can be tapered to be wider than the space at the top portion.

In accordance with another embodiment of the present invention, a method for fabrication of a semiconductor device includes forming a gate cut through a space between source/drain regions and corresponding contacts to the source/drain regions; forming an asymmetric via disposed on and wrapping around a side of a top portion of the gate cut; and connecting the asymmetric via, which is offset from a centerline of the power rail to the power rail.

In other embodiments, the gate cut can be deposited using additional dielectric material to raise a height of the gate cut above the corresponding contacts. Forming the gate cut can include forming the gate cut into a shallow trench isolation. The power rail can be formed by a subtractive etching process of a metal layer. The asymmetric via can be trimmed and dielectric portions can be formed within trimmed portions of the asymmetric via to ensure isolation between the asymmetric via and a neighboring metal line. The gate cut can be tapered to be wider than the space at the top portion.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows a cross-sectional view of a partially fabricated semiconductor device with shallow trench isolation, source/drain regions and middle of the line contacts formed, in accordance with an embodiment of the present invention;

FIG. 2 shows a cross-sectional view showing additional dielectric material added to a top surface of an interlevel dielectric layer, in accordance with an embodiment of the present invention;

FIG. 3 shows a cross-sectional view with a gate cut formed between the source/drain regions and extending between and above the contacts, in accordance with an embodiment of the present invention;

FIG. 4 shows a cross-sectional view showing dielectric material added to the additional dielectric material over a top surface of an interlevel dielectric layer, in accordance with an embodiment of the present invention;

FIG. 5 shows a cross-sectional view with the dielectric material patterned to locate openings to form vias, in accordance with an embodiment of the present invention;

FIG. 6 shows a cross-sectional view with vias formed including an asymmetric via, in accordance with an embodiment of the present invention;

FIG. 7 shows a cross-sectional view with a power rail formed and connected to the asymmetric via, in accordance with an embodiment of the present invention;

FIG. 8 shows a cross-sectional view with metal lines and a power rail formed in a subtractive etch process, in accordance with an embodiment of the present invention;

FIG. 9 shows a cross-sectional view with divots formed by a self-aligned etch to trim portions of the vias, in accordance with an embodiment of the present invention; and

FIG. 10 shows a cross-sectional view with divots and gaps between metal lines filled with dielectric material, in accordance with an embodiment of the present invention.

### DETAILED DESCRIPTION

In accordance with embodiments of the present invention, devices and methods are described which include connecting middle of the line (MOL) structures to power rails using an asymmetric via. In one embodiment, the asymmetric via can include a via bar. A via bar includes a longer length than a via. However, the via and via bar can be employed interchangeably herein. The via and the via bar include an asymmetric cross-section as will be described.

The via extends over a gate cut region. The gate cut region includes a dielectric bar or gate cut that divides source/drain (S/D) regions and their corresponding contacts. In one embodiment, the gate cut provides a partial landing position for the asymmetric via which can be placed over a top and one side of the gate cut. The gate cut provides separation between the asymmetric via and neighboring source/drain contact and increases alignment tolerance with the asymmetric via's placement. The asymmetry of the asymmetric via permits the maintenance of the size of the via itself by leveraging available space on a side of the gate cut that is more favorable to a larger mass of conductive material.

In one embodiment, a semiconductor device includes a gate cut region that is disposed between S/D regions of transistors and extends above middle of the line contacts (S/D contacts), which connect to the S/D regions of the transistors. An asymmetric via or via bar lands on one S/D contact and the gate cut. The gate cut can include a different dielectric fill material than an interlevel dielectric layer (ILD) formed over the S/D contact. The asymmetric via or via bar can be positioned to contact a power rail, e.g., an M1 power rail. In one embodiment, the gate cut can pass between MOL contacts, through the ILD layer, between S/D regions, and between gates.

In another embodiment, a semiconductor device includes a gate cut through MOL contacts and extending beyond the MOL contacts. An asymmetric via bar lands on one MOL contact and the gate cut. If the metal lines of power rail layers have a larger bottom dimension than a top dimension, the via or via bar is etched in the spacings between metal lines and filled with a dielectric material to form dielectric portions using, e.g., back end of the line (BEOL) dielectric.

In another embodiment, a method for fabricating a semiconductor device includes forming front end of the line (FEOL) devices with MOL contacts. An ILD and gate cut are formed through a cell boundary with different dielectric for the gate cut than the ILD. Additional ILD material is deposited to increase its level. An asymmetric via or via bar are patterned by etching the ILD selective to gate cut. Via or via bar metallization is performed and an additional power rail is formed over the via or via bar. In useful embodiments, the power rail is formed within a zone between two n-type field effect transistors (NFETs) (N2N) or a zone between two p-type field effect transistors (PFET) (P2P). Power rails provide positive supply voltage (VDD) or negative supply voltage (VSS) to respective PFETS and NFETs.

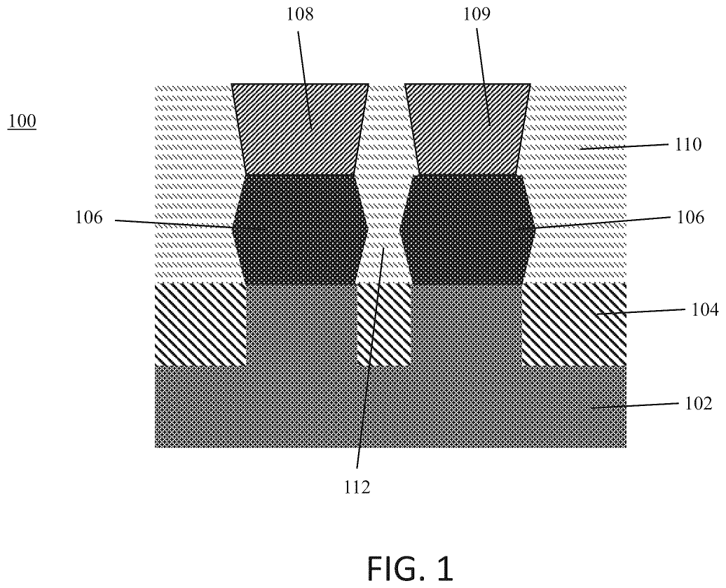

Referring now to the drawings in which like numerals represent the same or similar elements and initially to FIG. 1, devices and methods for manufacturing a semiconductor device is shown in accordance with embodiments of the present invention. A partially fabricated semiconductor device 100 includes a substrate 102. The substrate 102 can include any suitable substrate structure, e.g., a bulk semiconductor, a semiconductor-on-insulator (SOI) substrate, etc., and preferably includes a monocrystalline semiconductor. In one example, the substrate 102 can include a silicon-containing material. Illustrative examples of Si-containing materials suitable for the substrate 102 can include, but are not limited to Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

In one embodiment, one or more nanosheets (NS) (not shown) can be applied to the substrate 102 and patterned to expose and etch the substrate 102 for the formation of shallow trench isolation (STI) 104. The nanosheets can be employed for the formation of gate structures and device channels in some embodiments (not shown). The patterning of the nanosheets can include the formation of a hard mask, which may be formed by blanket depositing a layer of hard mask material, providing a patterned photoresist on top of the layer of hard mask material, and then etching the layer of hard mask material to provide the hard mask pattern for etching the nanosheets and the substrate 102. The patterned photoresist can be produced by applying a blanket photoresist layer to the surface of the hard mask material and exposing the photoresist layer to a pattern of radiation, and then developing the pattern into the photoresist layer utilizing resist developer. The pattern in the photoresist layer is transferred to the hard mask by an etch process.

The substrate 102 is further etched to form shallow trenches therein in accordance with the hard mask pattern, using an anisotropic etch process, such as a reactive ion etch (RIE) or an ion beam etch (IBE). STI 104 is formed in the etched trenches. STI 104 can be formed by depositing dielectric material, such as, e.g., SiO₂, SSiOₓN_{y}, SiCO or other suitable compounds. STI 104 can be deposited using chemical vapor deposition (CVD), although other deposition methods can be employed. The STI 104 can then be etched, e.g., by RIE, to a level of the substrate 102.

After that, dummy gate (not shown), gate spacer (not shown) is formed, followed by nanosheet stack recess, exposed sacrificial nanosheet indentation and inner spacer (not shown) formation. Then, an epitaxial growth process is performed to form source/drain regions 106. Source/drain regions 106 can include Si or SiGe and include faceted surfaces when epitaxial growth is not confined. In one embodiment, the source/drain regions 106 are separated by a space 112. In useful embodiments, the source/drain regions 106 can both be for N-type field effect transistors (NFETs) (N2N) or can both be for P-type field effect transistors (PFET) (P2P). N-type devices can include, e.g., Si, and P-type devices can include, e.g., SiGe. The source/drain regions 106 can be appropriately doped during the formation by epitaxial growth. For example, the source/drain regions 106 can be doped by introducing p dopants (e.g., B, Ga, etc.) or n dopants (e.g., P, As, etc.) during epitaxial formation. It should be understood that in other embodiments, P-type and N-type devices can be formed adjacent to one another and include space 112 therebetween.

A dielectric layer 110, such as, e.g., an interlevel dielectric layer (ILD) is formed on the device 100. The dielectric layer 110 can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The dielectric layer 160 can be deposited using CVD, although other deposition methods can be employed. CMP is then used to polish the dielectric layer 110 and expose dummy gate (not shown). Then dummy gate, sacrificial nanosheet layers are removed, followed by replacement gate (not shown) formation.

Middle of the line (MOL) contacts 108, 109 are formed to make connections with the source/drain regions 106. In useful embodiments, a silicide liner, such as Ti, Ni, NiPt is deposited first in the contact trenches, then a diffusion barrier can be formed in the contact trenches prior to a conductive fill. The diffusion barrier can include, e.g., TiN, TaN, or similar materials. A conductive fill is performed to fill the trenches on top of the diffusion barrier, if present. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, plasma enhanced CVD (PECVD), atomic layer deposition (ALD) or any other suitable deposition method. The conductive fill is planarized, e.g., by CMP, to form contacts 108, 109. It should be noted that gate structures (not shown) can be fabricated orthogonally to the source/drain regions 106.

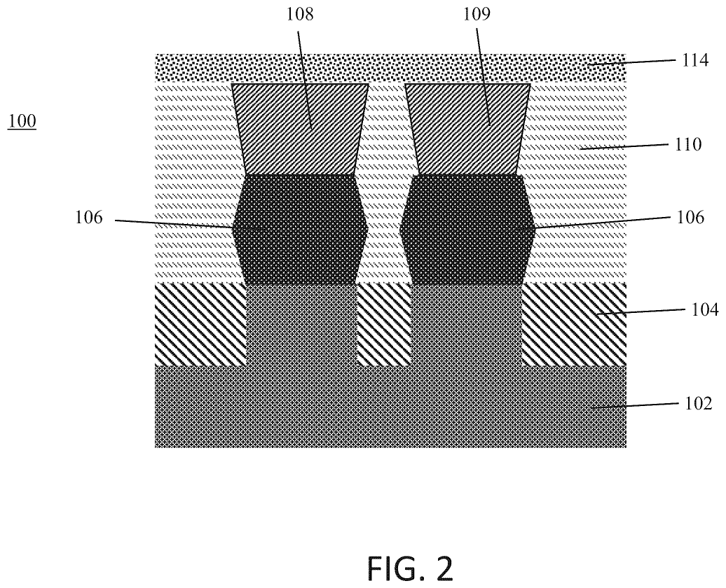

Referring to FIG. 2, a height of the dielectric layer 110 is increased to provide a higher position for the formation of a gate cut by depositing additional dielectric material 114. The additional dielectric material 114 can be deposited in a same or different manner as the dielectric layer 110. In one embodiment, the additional dielectric material 114 includes a same material as dielectric layer 110. The additional dielectric material 114 can be deposited using CVD, although other deposition methods can be employed.

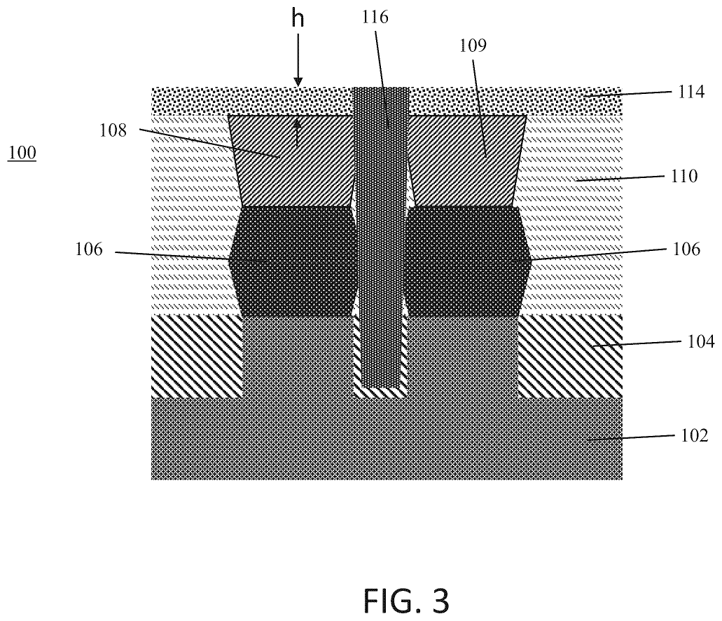

Referring to FIG. 3, in accordance with embodiments of the present invention, a dielectric bar or gate cut 116 is formed to separate and provide electrical isolation between structures. Gate cut 116 is patterned using lithographic patterning techniques. For example, lithography can be employed to pattern an etch mask (not shown). Trenches for the gates cuts 116 are etched in accordance with the etch mask and then the gate cuts 116 are filled with a dielectric material and a free surface is planarized. The gate cuts 116 separate gates (not shown), contacts 108, 109 and source/drain regions 106 from each other. The gate cut 116 can be formed down to the substrate 102 or can be formed into and through the STI 104.

The gate cut 116 extends over the contacts 108, 109 by a height h, which results from the deposition of additional dielectric material 114 minus the loss of the ILD during CMP process. The height h employs vertical space to create increased spacing between vias to be formed. The gate cut 116 can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H).

The material selected for the additional dielectric material 114 and dielectric material to be formed thereon in later steps should be selectively removable relative to the material of the gate cut 116. The gate cut 116 can be deposited using CVD, PECVD, although other deposition methods can be employed.

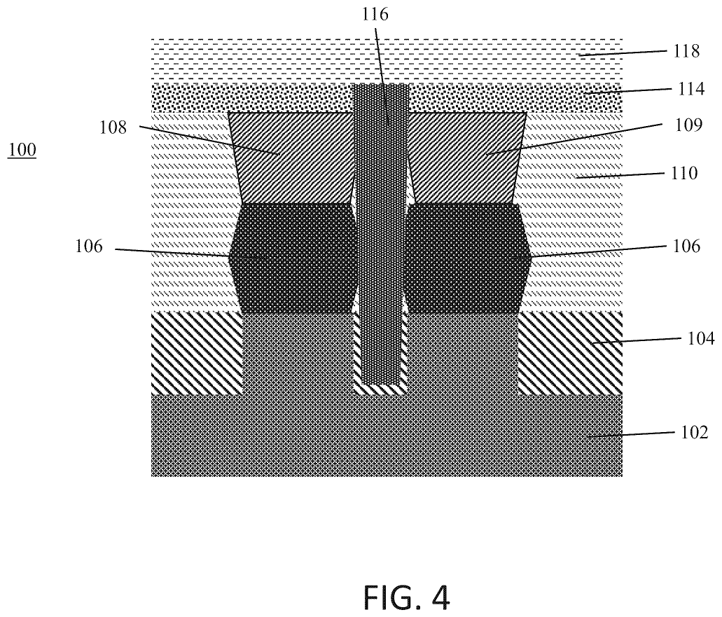

Referring to FIG. 4, a height of the dielectric layer 110 and additional dielectric material 114 is increased by dielectric material 118 to further provide a higher position for the formation of vias and or via bars. Dielectric material 118 can be deposited in a same or different manner as the dielectric layer 110 and/or dielectric material 114. In one embodiment, the dielectric material 118 includes a same material as dielectric layer 110. The dielectric material 118 can be deposited using CVD, although other deposition methods can be employed.

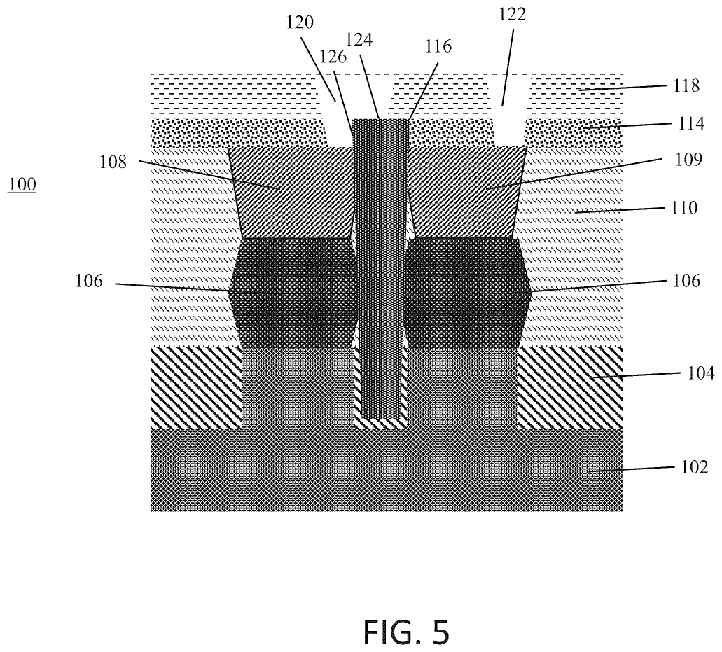

Referring to FIG. 5, via or via bar openings 120, 122 are formed in the dielectric material 114, 118. Openings 120, 122 can be patterned using photolithographic patterning techniques to create an etch mask to etch the openings 120, 122 with an anisotropic etch, e.g., RIE. Opening 120 exposes the underlying gate cut 116 and a portion of contact 108. The gate cut 116 is preferably tapered so that a top portion 124 is larger than the space 112 (FIG. 1) between source/drain regions 106. The top portion 124 adds alignment tolerance to the placement of opening 120 and eventually the formation of a via or via bar. Opening 120 is asymmetrically disposed over the gate cut 116 and a centerline of space 112. The asymmetry of opening 120 exposes one side 126 of the gate cut 116 while the opposing side remains buried in dielectric material 114. Opening 120 is offset to create distance between the opening 120 (in which a via or via bar will be formed) and the contact 109. By locating the opening 120 asymmetrically relative to the gate cut 116, better electrical isolation can be provided between the via to be formed and contact 109.

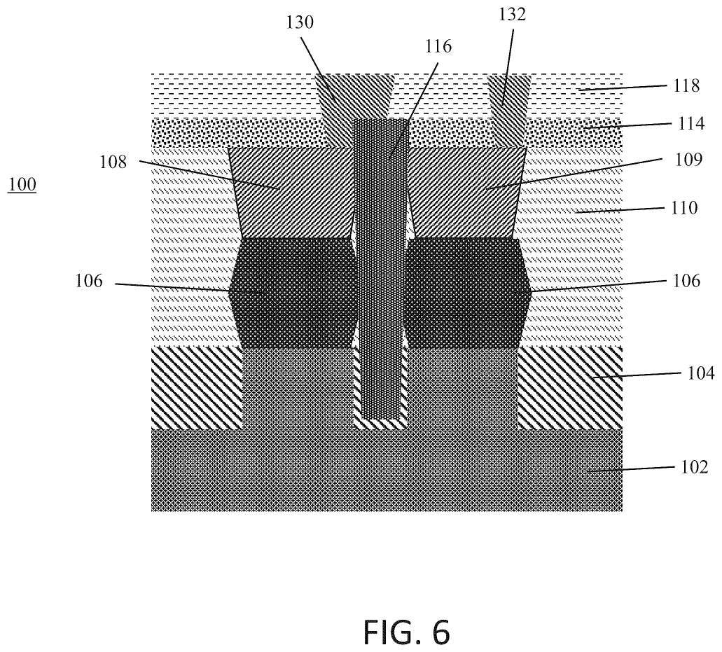

Referring to FIG. 6, metallization is provided for the formation of asymmetrical via or via bar 130 and via 132. Openings 120, 122 may be lined by first depositing a diffusion barrier metal liner (not shown), such as TiN, or TaN. Then, a conductive fill is performed to fill the openings 120, 122 on top of the diffusion barrier, if present. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., plating, CVD, PECVD, atomic layer deposition (ALD) or any other suitable deposition method. The conductive fill is planarized, e.g., by CMP, to form asymmetrical via or via bar 130 and via 132. A standard via, or simply via, is a vertical interconnect that connects between layers. A via bar is a via that includes a longer length than a standard via. While the terms via and via bar can be used interchangeably, the asymmetrical via 130 can run a length in a direction into/out of the page.

Asymmetrical via 130 is formed on top of gate cut 116 and covers a side of the gate cut 116. The portion of the asymmetrical via 130 that is formed on the side of the gate cut 116 makes electrical contact with contact 108.

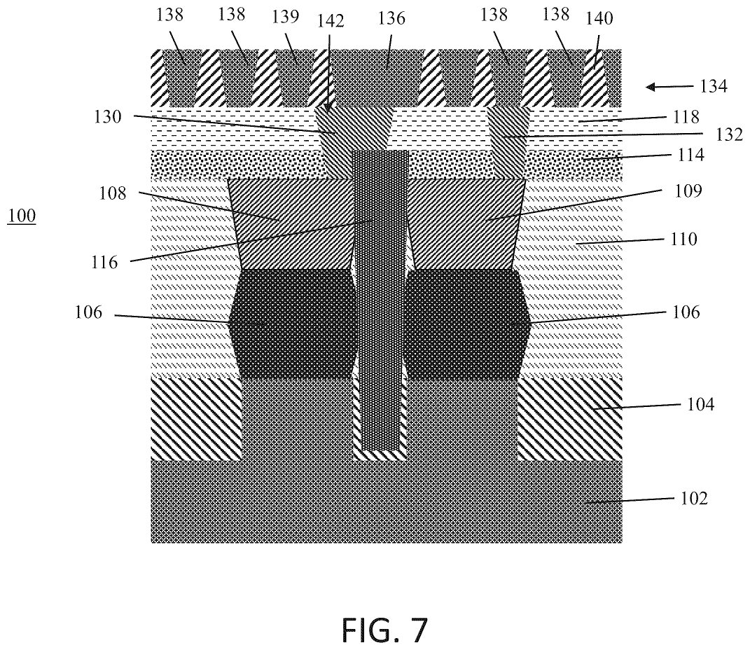

Referring to FIG. 7, processing continues with the formation of back end of the line (BEOL) layer 134, which can include metal structures and dielectric layers to complete metallization layers of the device 100 and provide electrical access to the devices formed thereon. In one embodiment, the BEOL layer 134 includes a metal layer (e.g., M1), which includes metal lines 138 and a power rail 136. A dielectric layer 140 is deposited over the device 100 and patterned using an an etch mask and etch process. The metal lines 138 and power rail 136 are formed by performing a conductive fill followed by a planarization process. The conductive fill may be performed after the formation of a diffusion barrier. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, atomic layer deposition (ALD) or any other suitable deposition method. The conductive fill is planarized, e.g., by CMP.

A cross-section of the asymmetrical via 130 shows that it is not aligned with the power rail 136. Instead, the asymmetrical via 130 is offset and asymmetric relative to a centerline through the gate cut 116 and the power rail 136. In the embodiment shown in FIG. 7, the power rail 136 and metal lines 138 have a narrower base and a larger top in cross-section. With this geometry, an end portion 142 of the asymmetrical via 130 falls between the power rail 136 and a next adjacent metal line 139. Adequate dielectric material exists between these components, namely, between the power rail 136, the next adjacent metal line 139 and the asymmetrical via 130.

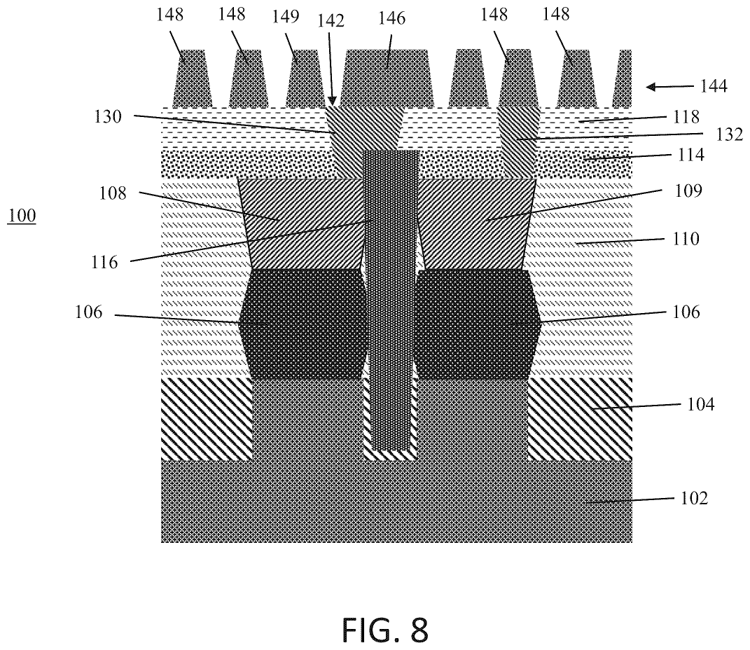

Referring to FIG. 8, in an alternate embodiment, processing continues with the formation of BEOL layer 144, which can include metal structures and dielectric layers to complete metallization layers of the device 100 and provide electrical access to the devices formed thereon. In one embodiment, the BEOL layer 144 includes a metal layer (e.g., M1), which includes metal lines 148 and a power rail 146. The metal lines 148 and power rail 146 are formed by performing a subtractive etch on a metal layer (e.g., a conductive plate) deposited over the device 100. The conductive plate can include materials, such as, e.g., Cu, Ru, Mo, Rh, W, Ir, and alloys or combinations of these and other conductive materials. In a particularly useful embodiment, the conductive fill includes Ru. The conductive deposition can be formed using a deposition method, such as, e.g., physical vapor deposition (PVD), plating, CVD, PECVD, ALD or any other suitable deposition method.

A cross-section of the asymmetrical via 130 shows that it is not aligned with the power rail 146. Instead, the asymmetrical via 130 is offset and asymmetric relative to a centerline through the gate cut 116 and the power rail 146. In the embodiment shown in FIG. 8, the power rail 146 and metal lines 148 have a wider base and a narrower top in cross-section. With this geometry, the end portion 142 of the asymmetrical via 130 falls between the power rail 146 and a next adjacent metal line 149. Inadequate dielectric material may exist between these components, namely, between the next adjacent metal line 139 and the asymmetrical via 130.

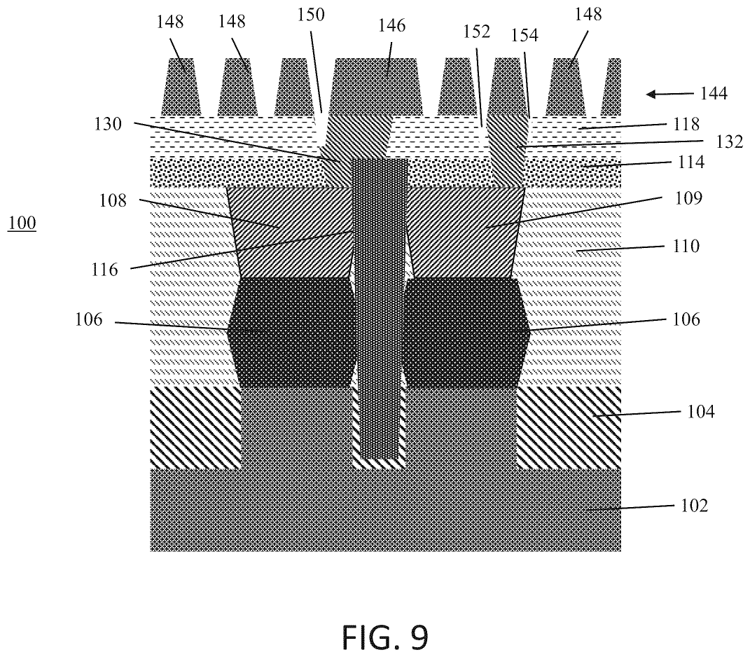

Referring to FIG. 9, a via trim process is performed to ensure adequate dielectric material is present between vias and surrounding conductive structures. A selective etch is performed that etches exposed portions of the asymmetrical via 130 and via 132. In one embodiment, the etch process includes RIE and is selective to the metal of layer 144. The etch process is self-aligned and forms trenches or divots 150, 152, 154 around the asymmetrical via 130 and via 132 where conductive material has been trimmed.

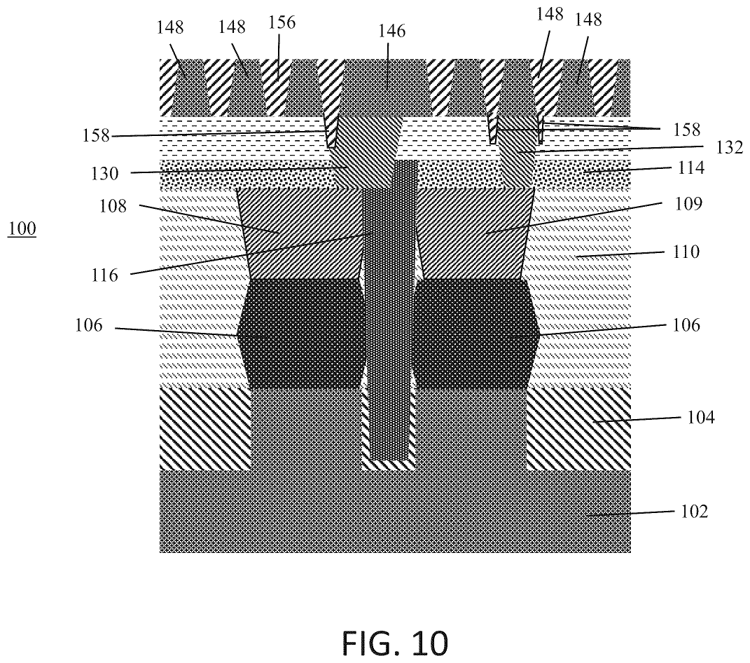

Referring to FIG. 10, a dielectric layer 156 is deposited, which can include a same material as dielectric layer 110 to fill in gaps between buried power rails 146 and metal lines 148 and to fill divots 150, 152, 154 to form dielectric portions 158. The dielectric layer 156 can be planarized. Fabrication can continue with the formation of additional BEOL layers, which are fabricated on the dielectric layer 156 and connections are made to the power rails 146 and metal lines 148.

In accordance with embodiments of the present invention, the gate cut 116 is placed within a tight transistor to transistor (T2T) region and is achieved without impact to wire routing of other wiring structures. In addition, vias are provided that connect contacts power rails through a location or region between NFETs or PFETs. The present embodiments make connecting to the power rail easily achievable and reliable, especially in view of decreasing node sizes.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising.” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a gate cut disposed through a space between source/drain regions and corresponding source/drain contacts, the gate cut having a top surface above a top surface of the source/drain contacts; and
an asymmetric via disposed on and wrapping around a side of a top portion of the gate cut to connect one of the source/drain contacts to a power rail.

2. The semiconductor device as recited in claim 1, wherein the gate cut is disposed within a shallow trench isolation.

3. The semiconductor device as recited in claim 1, further comprising a via connected to the other one of the source/drain contacts at a position opposite the gate cut.

4. The semiconductor device as recited in claim 1, wherein the asymmetric via includes a via bar with an asymmetric cross-section.

5. The semiconductor device as recited in claim 1, wherein the asymmetric via is offset from a centerline of the power rail.

6. The semiconductor device as recited in claim 1, further comprising dielectric portions disposed within trimmed portions of the asymmetric via to ensure isolation between the asymmetric via and a neighboring metal line, when a lower dimension of a cross-section of the neighboring metal line exceeds a top dimension of the cross-section of the neighboring metal line.

7. The semiconductor device as recited in claim 1, wherein the gate cut is tapered to be wider than the space at the top portion.

8. A semiconductor device, comprising:
a first source/drain region;
a second source/drain region adjacent to the first source/drain region, the first source/drain region and second source/drain region having a space therebetween;
a first contact connected to the first source/drain region;
a second contact connected to the second source/drain region;
a gate cut disposed through the space and extending between and above the first contact and the second contact; and
an asymmetric via disposed on and wrapping around a side of a top portion of the gate cut to connect the first contact to a power rail.

9. The semiconductor device as recited in claim 8, wherein the gate cut is disposed within a shallow trench isolation.

10. The semiconductor device as recited in claim 8, further comprising a via connected to the second contact at a position opposite the gate cut.

11. The semiconductor device as recited in claim 8, wherein the asymmetric via includes a via bar with an asymmetric cross-section.

12. The semiconductor device as recited in claim 8, wherein the asymmetric via is offset from a centerline of the power rail.

13. The semiconductor device as recited in claim 8, further comprising dielectric portions disposed within trimmed portions of the asymmetric via to ensure isolation between the asymmetric via and a neighboring metal line, when a lower dimension of a cross-section of the neighboring metal line exceeds a top dimension of the cross-section of the neighboring metal line.

14. The semiconductor device as recited in claim 8, wherein the gate cut is tapered to be wider than the space at the top portion.

15. A method for fabrication of a semiconductor device, comprising:
forming a gate cut through a space between source/drain regions and corresponding contacts to the source/drain regions;
forming an asymmetric via disposed on and wrapping around a side of a top portion of the gate cut; and
connecting the asymmetric via to a power rail, where the asymmetric via is offset from a centerline of the power rail.

16. The method as recited in claim 15, wherein forming the gate cut includes:
depositing additional dielectric material to raise a height of the gate cut above the corresponding contacts.

17. The method as recited in claim 15, wherein forming the gate cut includes forming the gate cut into a shallow trench isolation.

18. The method as recited in claim 15, wherein the power rail is formed by a subtractive etching process of a metal layer.

19. The method as recited in claim 18, further comprising:
trimming the asymmetric via; and
forming dielectric portions within trimmed portions of the asymmetric via to ensure isolation between the asymmetric via and a neighboring metal line.

20. The method as recited in claim 15, wherein the gate cut is tapered to be wider than the space at the top portion.
